(19) United States
(12) Patent Application Publication
(10) Pub. No.: US 2026/0292999 A1
(43) Pub. Date: Sep. 24, 2026

(54) MANUFACTURING METHOD FOR COMPONENT MOUNTING SUBSTRATE

(71) Applicant: PANASONIC INTELLECTUAL PROPERTY MANAGEMENT CO., LTD., Kadoma-shi, Osaka (JP)

(72) Inventors: Tadahiko SAKAI, Fukuoka (JP); Tadashi MAEDA, Fukuoka (JP); Yuki YOSHIOKA, Fukuoka (JP)

(21) Appl. No.: 19/477,559

(22) PCT Filed: Feb. 26, 2024
(86) PCT No.: PCT/JP2024/006859

§ 371 Date: Oct. 22, 2025

(30) Foreign Application Priority Data
Apr. 27, 2023 (JP) 2023-073645

(51) Int. Cl. H05K 3/341; H05K 3/3494

(52) U.S. Cl. CPC H05K 3/341; H05K 3/3494

(57) ABSTRACT

Disclosed is a manufacturing method for a component mounting board. The method includes, in order: a solder precoat portion formation step of forming solder precoat portions on a plurality of first lands on a first surface of a circuit board; a first arrangement step of arranging a plurality of first components on the solder precoat portions; a first reflow step of soldering the plurality of first components by heating the circuit board on which the plurality of first components are arranged; a solder paste application step of applying solder paste to a plurality of second lands on a second surface of the circuit board; a second arrangement step of arranging a plurality of second components on the solder paste; and a second reflow step of soldering the plurality of second components by heating the circuit board on which the plurality of second components are arranged. Soldering on the first surface is more difficult than soldering on the second surface.

### TECHNICAL FIELD

The present disclosure relates to a manufacturing method for a component mounting board.

### BACKGROUND ART

As a method for mounting a plurality of electronic components on a substrate, there is known a reflow method by which the electronic components are mounted on the substrate using solder paste.

Claim 1 of PTL 1 (Japanese Laid-Open Patent Publication No. H06-334323) describes “a solder precoating method comprising applying solder to lands on a surface of a substrate by solder paste printing, and thereafter melting the solder on the lands in a reflow step, without mounting a component on a land to be precoated with solder”.

### CITATION LIST

### Patent Literature

PTL 1: Japanese Laid-Open Patent Publication No. H06-334323

### SUMMARY OF INVENTION

### Technical Problem

To increase the component mounting density, components are mounted on both surfaces of a circuit board. However, in mounting components on both surfaces of a circuit board, the conditions for mounting components on one surface are different from the conditions for mounting components on the other surface, and thus failures readily occur according to the conventional method. The higher the mounting density, the more likely failures are to occur during mounting. In light of such circumstances, one object of the present disclosure is to provide a manufacturing method for a component mounting board that is unlikely to cause failures.

### Solution to Problem

An aspect of the present disclosure relates to a first manufacturing method for a component mounting board. The first manufacturing method is a manufacturing method for a component mounting board including a circuit board having a first surface and a second surface on an opposite side to the first surface, and a plurality of components mounted on both surfaces of the circuit board, the method including, in order: a solder precoat portion formation step of forming solder precoat portions on a plurality of first lands on the first surface of the circuit board; a first arrangement step of arranging a plurality of first components on the solder precoat portions; a first reflow step of soldering the plurality of first components by heating the circuit board on which the plurality of first components are arranged; a solder paste application step of applying solder paste to a plurality of second lands on the second surface of the circuit board; a second arrangement step of arranging a plurality of second components on the solder paste; and a second reflow step of soldering the plurality of second components by heating the circuit board on which the plurality of second components are arranged, soldering on the first surface being more difficult than soldering on the second surface.

Another aspect of the present disclosure relates to a second manufacturing method for a component mounting board. The second manufacturing method is a manufacturing method for a component mounting board including a circuit board having a first surface and a second surface on the opposite side to the first surface, and a plurality of components mounted on both surfaces of the circuit board, the method including: a solder precoat portion formation step of forming solder precoat portions on a plurality of first lands on the first surface of the circuit board; a first arrangement step of arranging a plurality of first components on the solder precoat portions; a first reflow step of soldering the plurality of first components by heating the circuit board on which the plurality of first components are arranged; a solder paste application step of applying solder paste to a plurality of second lands on the second surface of the circuit board; a second arrangement step of arranging a plurality of second components on the solder paste; and a second reflow step of soldering the plurality of second components by heating the circuit board on which the plurality of second components are arranged, lands having an area of 0.04 mm² or less among the plurality of first lands being greater in number than lands having an area of 0.04 mm² among the plurality of second lands.

Another aspect of the present disclosure relates to a third manufacturing method for a component mounting board. The third manufacturing method is a manufacturing method for a component mounting board including a circuit board having a first surface and a second surface on the opposite side to the first surface, and a plurality of components mounted on both surfaces of the circuit board, the method including: a solder precoat portion formation step of forming solder precoat portions on a plurality of first lands on the first surface of the circuit board; a first arrangement step of arranging a plurality of first components on the solder precoat portions; a first reflow step of soldering the plurality of first components by heating the circuit board on which the plurality of first components are arranged; a solder paste application step of applying solder paste to a plurality of second lands on the second surface of the circuit board; a second arrangement step of arranging a plurality of second components on the solder paste; and a second reflow step of soldering the plurality of second components by heating the circuit board on which the plurality of second components are arranged, lands adjacent with a distance of 0.1 mm or less therebetween among the plurality of first lands being greater in number than lands adjacent with a distance of 0.1 mm or less therebetween among the plurality of second lands.

Another aspect of the present disclosure relates to a fourth manufacturing method for a component mounting board. The fourth manufacturing method is a manufacturing method for a component mounting board including a circuit board having a first surface and a second surface on the opposite side to the first surface, and a plurality of components mounted on both surfaces of the circuit board, the method including: a solder precoat portion formation step of forming solder precoat portions on a plurality of first lands on the first surface of the circuit board; a first arrangement step of arranging a plurality of first components on the solder precoat portions; a first reflow step of soldering the plurality of first components by heating the circuit board on which the plurality of first components are arranged; a solder paste application step of applying solder paste to a plurality of second lands on the second surface of the circuit board; a second arrangement step of arranging a plurality of second components on the solder paste; and a second reflow step of soldering the plurality of second components by heating the circuit board on which the plurality of second components are arranged, the plurality of first components including micro components having a size not larger than an 0402 size prescribed by JIS, and the micro components adjacent with a distance of 0.1 mm or less therebetween among the plurality of first components being greater than the micro components adjacent with a distance of 0.1 mm or less therebetween among the plurality of second components.

### Advantageous Effects of Invention

According to a manufacturing method of the present disclosure, it is possible to suppress the occurrence of failures in the manufacture of component mounting boards.

While novel features of the present invention are set forth in the appended claims, the present invention, both in terms of structure and content, together with other objects and features of the present invention, will be better understood from the following detailed description taken in conjunction with the drawings.

### BRIEF DESCRIPTION OF DRAWINGS

FIG. 1A is a diagram schematically showing one step of part of an example of a manufacturing method according to a first embodiment.

FIG. 1B is a diagram schematically showing an example of a step subsequent to FIG. 1A.

FIG. 1C is a diagram schematically showing an example of a step subsequent to FIG. 1B.

FIG. 1D is a diagram schematically showing an example of a step subsequent to FIG. 1C.

FIG. 1E is a diagram schematically showing an example of a step subsequent to FIG. 1D.

FIG. 2A is a diagram schematically showing an example of a step subsequent to FIG. 1E.

FIG. 2B is a diagram schematically showing an example of a step subsequent to FIG. 2A.

FIG. 2C is a diagram schematically showing an example of a step subsequent to FIG. 2B.

FIG. 3 is a diagram schematically showing an example of the step shown in FIG. 1C.

FIG. 4 is a diagram showing another example of manufacturing steps according to the first embodiment.

FIG. 5A is a diagram showing an example of arrangement of first lands on a circuit board before mounting components.

FIG. 5B is a diagram schematically showing a first surface of the circuit board after mounting components.

FIG. 6A is a diagram for describing an example of distances between adjacent lands.

FIG. 6B is a diagram for describing another example of distances between adjacent lands.

FIG. 7 is a diagram for describing a distance between adjacent components.

FIG. 8A is a diagram showing an example of arrangement of second lands on a circuit board before mounting components.

FIG. 8B is a diagram schematically showing an example of a second surface of the circuit board after mounting components.

### DESCRIPTION OF EMBODIMENTS

The following describes embodiments of the present disclosure giving examples, but the present disclosure is not limited to the examples described below. In the following description, specific numerical values and materials may be illustrated, but other numerical values and other materials may be applied as long as the advantageous effects of the present disclosure can be obtained. Herein, the phrase “numerical value A to numerical value B” includes numerical value A and numerical value B and can be read as “numerical value A or greater and numerical value B or less”. In the following description, when lower and upper limits of numerical values related to specific physical properties or conditions are illustrated, any of the illustrated lower limits and any of the illustrated upper limits can be combined as desired, as long as the lower limit is not greater than the upper limit. In the following description, when examples of constituent elements or methods are listed, only one of the listed examples may be used, or a plurality of the listed examples may be used in combination, unless otherwise specified.

### Manufacturing Method for Component Mounting Substrate

A manufacturing method according to the present embodiment may be referred to as “manufacturing method (M)” below. The manufacturing method (M) is a manufacturing method for a component mounting board including a circuit board having a first surface and a second surface on the opposite side to the first surface, and a plurality of components mounted on both surfaces of the circuit board. The manufacturing method (M) includes, in order, a solder precoat portion formation step, a first arrangement step, a first reflow step, a solder paste application step, a second arrangement step, and a second reflow step. Soldering on the first surface is more difficult than soldering on the second surface.

When mounting components on the second surface, it is necessary to place the components from above the second surface while supporting the first surface. Therefore, if components are mounted on the first surface, it is difficult to mount components on the second surface. In the manufacturing method (M), components are mounted on the first surface on which soldering is more difficult, before mounting components on the second surface. This makes it possible to reduce failures when mounting components. In the manufacturing method (M), the surface of the circuit board on which soldering is more difficult, out of the front and back surfaces, is set as the first surface, and thus it is possible to mount components on both surfaces of the circuit board at a low failure rate. The steps of the manufacturing method (M) will be described below.

### Solder Precoat Portion Formation Step

The solder precoat portion formation step is a step of forming solder precoat portions on a plurality of first lands on the first surface of the circuit board. The method for forming solder precoat portions is not particularly limited, and a known method may be used. In an example of the method, first, solder paste (cream solder) is applied to the first lands. The solder paste is then heated until solder particles in the solder paste melt, and then cooled, thereby forming solder precoat portions (solder layers) on the first lands. The solder paste may be solder paste containing solder particles and other components (e.g., flux). The solder paste is not particularly limited, and may be a known solder paste used to form solder precoat portions. The method for applying the solder paste is not particularly limited, and a known method (e.g., screen printing) may be used.

The circuit board is not particularly limited, and a known circuit board may be used. The circuit board includes a substrate, a plurality of first lands formed on one surface of the substrate, and a plurality of second lands formed on the other surface of the substrate. The substrate may be an insulating plate-like substrate. If necessary, the substrate has wiring that passes through the substrate.

Of the two surfaces of the circuit board, the first surface of the circuit board is the surface on which soldering is more difficult.

### First Arrangement Step

The first arrangement step is a step of arranging a plurality of first components on the solder precoat portions. The method for arranging the components is not particularly limited, and any known arrangement method may be used. For example, the first components may be arranged on the solder precoat portions using a chip mounter.

The first components include components of various types and sizes. The first components may include components having a size not larger than the 0402 size prescribed by the Japanese Industrial Standards (JIS). Hereinafter, components having a size not larger than the 0402 size prescribed by JIS may be referred to as “micro components”. The 0402 size prescribed by JIS is the size of a planar shape measuring 0.4 mm or less in length and 0.2 mm or less in width.

The first components may include components larger than the 0402 size. The components (first components and second components) mounted on the circuit board are not particularly limited and include general components to be mounted on circuit boards. Examples of the components include various chip components (e.g., electronic components), chip size packages (CSPs), ball grid arrays (BGAs), connectors, and other components used in electronic devices. The first components and the second components may each include components having a size not smaller than the 1608 size prescribed by JIS, and may include components having a size not larger than the 0402 size prescribed by JIS.

### First Reflow Step

The first reflow step is a step of soldering the plurality of first components by heating the circuit board on which the plurality of first components are arranged. The first reflow step can be performed by heating the solder precoat portions until the solder precoat portions melts and then cooling the same. The heating and cooling of the solder precoat portions is usually performed by heating and cooling the entire circuit board on which the first components are arranged. The first reflow step may be performed using a known reflow furnace.

### Solder Paste Application Step

The solder paste application step is a step of applying solder paste to the plurality of second lands on the second surface of the circuit board. The solder paste is not particularly limited, and solder paste used for surface mounting of electronic components may be used. For example, the solder paste may be solder paste containing solder particles and other components (e.g., flux). The method for applying the solder paste is not limited, and the application method described above for the solder precoat portion formation step may be used. The solder used to form the solder precoat portions and the solder used in the solder paste application step may be the same or may be different.

### Second Arrangement Step

The second arrangement step is a step of arranging the plurality of second components on the solder paste applied in the solder paste application step. The method for arranging the second components is not particularly limited, and the method described above for the first arrangement step may be used. The second components may include components of various types and sizes.

### Second Reflow Step

The second reflow step is a step of soldering the plurality of second components by heating the circuit board on which the plurality of second components are arranged. The second reflow step can be performed by heating the solder paste until the solder particles in the solder paste melt and then cooling the same. The heating and cooling of the solder paste is usually performed by heating and cooling the entire circuit board on which the second components are arranged. The second reflow step may be performed using a known reflow furnace.

Through the above steps, the plurality of first components are mounted on the first surface of the circuit board, and the plurality of second components are mounted on the second surface. In one aspect, the manufacturing method (M) includes a first mounting step of mounting the plurality of first components on the first surface, and a second mounting step of mounting the plurality of second components on the second surface. The first mounting step includes the solder precoat portion formation step, the first arrangement step, and the first reflow step, in this order. Each step of the first mounting step is usually performed with the first surface facing up and the second surface supported from below.

The second mounting step includes the solder paste application step, the second arrangement step, and the second reflow step, in this order. Each step of the second mounting step is usually performed with the second surface facing up and the first surface supported from below.

As described above, soldering on the first surface is more difficult than soldering on the second surface. Empirically, if at least one (e.g., any one) of the following conditions (1) to (4) is satisfied, it can be said that soldering on the first surface is more difficult than soldering on the second surface. In other words, the condition “soldering on the first surface is more difficult than soldering on the second surface” can be read as at least one (e.g., any one) of the following conditions (1) to (4):
(1) The plurality of first components includes micro components having a size not larger than the 0402 size prescribed in JIS, and the micro components included in the plurality of first components are greater in number than the micro components included in the plurality of second components.
(2) Lands having an area of 0.04 mm² or less among the plurality of first lands are greater in number than lands having an area of 0.04 mm² or less among the plurality of second lands.
(3) Lands adjacent with a distance of 0.1 mm or less therebetween among the plurality of first lands are greater in number than lands adjacent with a distance of 0.1 mm or less therebetween among the plurality of second lands.
(4) The plurality of first components include micro components having a size not larger than the 0402 size prescribed by JIS, and the micro components adjacent with a distance of 0.1 mm or less therebetween among the plurality of first components are greater in number than the micro components adjacent with a distance of 0.1 mm or less therebetween among the plurality of second components.

Regarding the condition (1), soldering becomes more difficult as the number of micro components increases. The number of micro components included in the plurality of second components may be zero. That is, the plurality of second components may not include any micro components.

Regarding the condition (2), soldering becomes more difficult as the number of lands with small areas increases.

Regarding the condition (3), soldering becomes more difficult as the spacing between adjacent lands decreases.

Regarding the condition (4), soldering becomes more difficult as the number of micro components adjacent with a distance of 0.1 mm or less therebetween increases.

The manufacturing method (M) may include other steps in addition to the steps described above. Examples of the other steps include a step of inspecting the state of component arrangement in the component arrangement step, a step of inspecting the state of soldering in the reflow step, a step of inspecting the state of solder paste application in the solder paste application step, and other steps. For example, the manufacturing method (M) may include a flattening step of pressing down the solder precoat portions before the first arrangement step. The flattening step is a step of pressing down and further flattening the solder precoat portions. Performing the flattening step suppresses displacement of the first components arranged on the solder precoat portions in the first arrangement step from predetermined positions.

The flattening step can be performed by pressing the solder precoat portions with a pressing member from above the first surface while supporting the second surface from below. The pressing member may be a plate-shaped member or a roller-shaped member.

In the flattening step, it is important to prevent the circuit board from bending in the thickness direction due to the load of the pressing member. This is because if the circuit board bends in the thickness direction, the solder precoat portions cannot be flattened. Therefore, the flattening step is preferably performed while the circuit board is supported by a flat support base (flat table). In the manufacturing method (M), components are mounted on the first surface in a state where components are not mounted on the second surface, and thus the second surface can be supported by a flat table in the flattening step. Using a flat table makes it possible to not only uniformly support the second surface, but also reduce the manufacturing cost of component mounting boards.

The second surface may, however, be supported by a support means other than a flat table as long as it is possible to prevent bending of the circuit board during flattening. Examples of the support means include a plurality of pins, a support means that supports the vicinity of the outer edge of the substrate, a support means that has recesses corresponding to the first components, and the like. These support means may also be used in combination.

The manufacturing method (M) may include a flux application step of applying flux (solder flux) to the solder precoat portions after the solder precoat portion formation step and before the first arrangement step. If the manufacturing method (M) includes the flux application step and the flattening step, the flux application step can be performed before the flattening step. The flux and the flux application method are not particularly limited, and known flux and a known method (e.g., screen printing) may be used. Solder paste may be applied instead of flux.

Each step of mounting the plurality of second components on the second surface (each step of the second mounting step) may be performed while the circuit board is supported by a support means having a structure that does not interfere with the plurality of first components soldered to the first surface. For example, a support means that supports only a portion of the substrate may be used. Examples of such a support means include a plurality of pins, a support means that supports the vicinity of the outer edge of the substrate, a support means that has recesses corresponding to the first components, and the like. These support means may also be used in combination.

Hereinafter, examples of embodiments according to the present disclosure will be specifically described with reference to the drawings. The embodiments described below can be modified based on the above description. The matters described below may also be applied to the above embodiments. In the embodiments described below, matters that are not essential to the manufacturing method (M) according to the present disclosure may be omitted. In the drawings referred to below, some reference signs may be omitted.

### First Embodiment

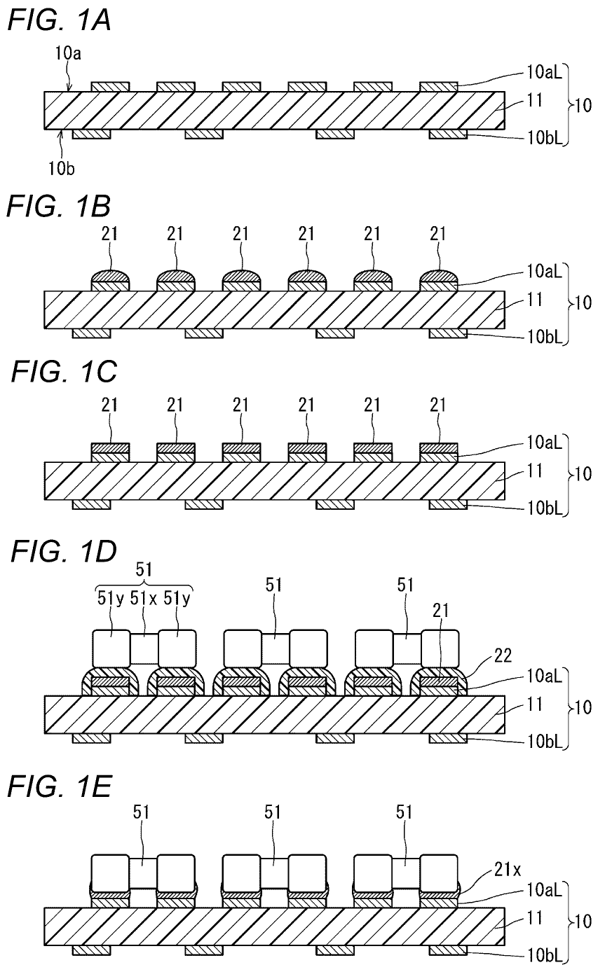

In a first embodiment, an example of the manufacturing method (M) according to the present disclosure will be described. FIG. 1A schematically shows a circuit board 10 used in the first embodiment. The circuit board 10 has a first surface 10a and a second surface 10b on the opposite side to the first surface 10a. The circuit board 10 includes a substrate 11, a plurality of first lands 10aL formed on the first surface 10a, and a plurality of second lands 10bL formed on the second surface 10b. Soldering on the first surface 10a is more difficult than soldering on the second surface 10b.

The first surface 10a and the second surface 10b each have wiring (not shown) including lands formed thereon. The wiring on the first surface 10a is connected to the wiring on the second surface 10b as needed by wiring (not shown) formed inside the substrate 11.

In the manufacturing method (M), a first mounting step is performed to mount a plurality of first components on the first surface 10a. The first mounting step is performed in a state where the first surface 10a faces up and the second surface 10b is supported. In the first mounting step, first, solder precoat portions 21 are formed on the plurality of first lands 10aL on the first surface 10a as shown in FIG. 1B.

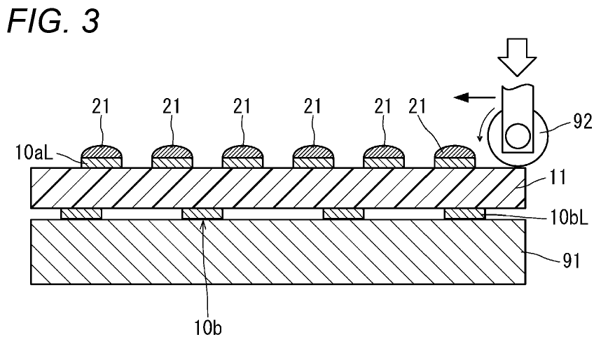

Next, as shown in FIG. 1C, a flattening step is performed to press down and flatten the tops of the solder precoat portions 21. The flattening step may be performed by moving a roller 92 and pressing down the tops of the solder precoat portions 21 with the second surface 10b supported by a flat table 91, as shown in FIG. 3.

Next, as shown in FIG. 1D, flux 22 is applied so as to cover the solder precoat portions 21, and a plurality of first components 51 are arranged on the solder precoat portions 21 with the flux 22 therebetween. The first components 51 shown in FIG. 1D are chip-type electronic components that have terminal portions 51y on both ends of a main body portion 51x, for example. As described above, solder paste may be applied instead of flux, but in that case, the solder paste needs to be applied so as not short-circuit with adjacent lands.

Next, the circuit board 10 on which the plurality of first components 51 are arranged is heated and cooled to solder the plurality of first components 51. The solder precoat portions 21 melt to become liquid solder when the circuit board 10 is heated, and oxide films on the terminal portions 51y are removed by the reduction action of the flux 22, thus allowing the liquid solder to spread over the surfaces of the terminal portions 51y. The circuit board 10 is then cooled to solidify the liquid solder, completing the soldering step. As shown in FIG. 1E, the first components 51 are connected to the first lands 10aL by the solder 21x.

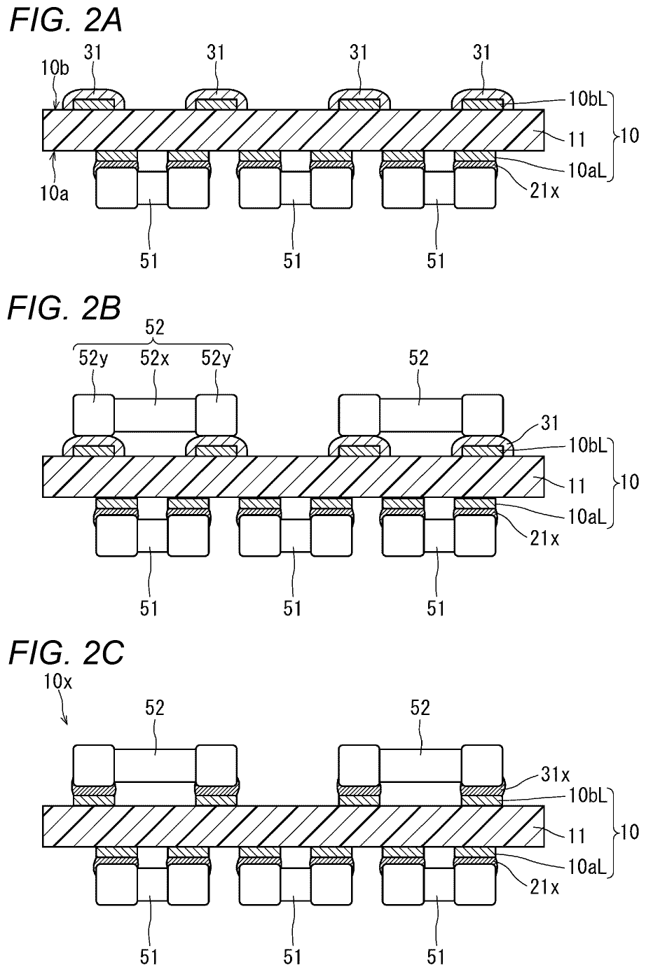

Next, a plurality of second components are mounted on the second surface 10b in a second mounting step. The second mounting step is performed in a state where the second surface 10b faces up and the first surface 10a is supported. In the second mounting step, first, as shown in FIG. 2A, solder paste 31 is applied to the plurality of second lands 10bL on the second surface 10b of the circuit board 10.

Next, as shown in FIG. 2B, a plurality of second components 52 are arranged on the solder paste 31. The second components 52 shown in FIG. 2B are exemplified by chip-type electronic components having terminal portions 52y at both ends of a main body portion 52x. Next, as shown in FIG. 2C, the circuit board 10 on which the plurality of second components 52 are arranged is heated and cooled to solder the plurality of second components 52. The second components 52 are connected to the second lands 10bL by solder 31x. In this way, a component mounting board 10x is obtained in which components are mounted on both the first surface 10a and the second surface 10b.

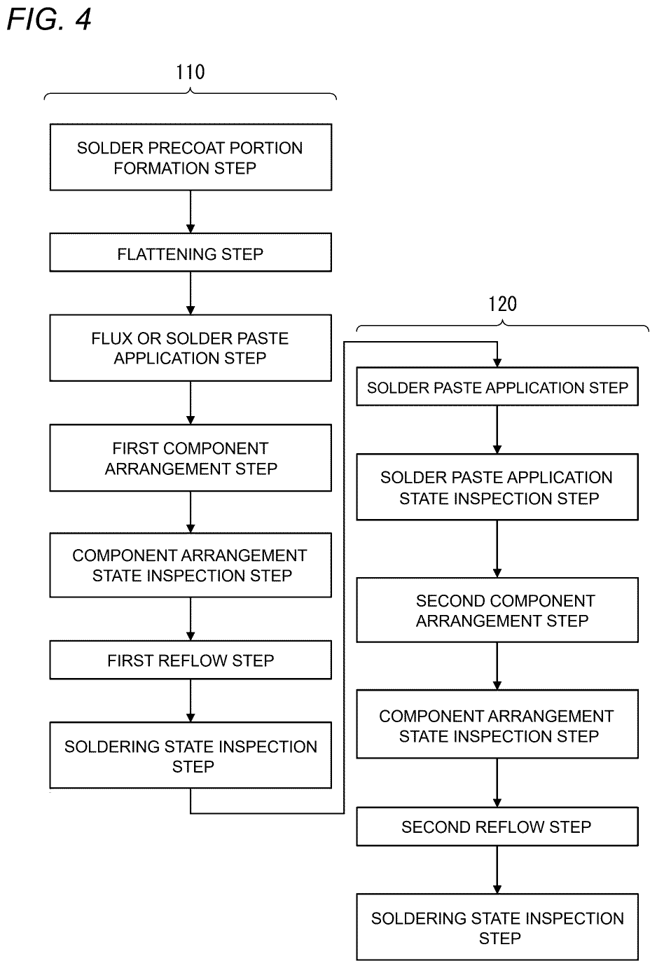

FIG. 4 shows an example of steps of the manufacturing method (M). The manufacturing method shown in FIG. 4 includes a first mounting step 110 and a second mounting step 120. The first mounting step 110 and the second mounting step 120 each include the steps shown in FIG. 4.

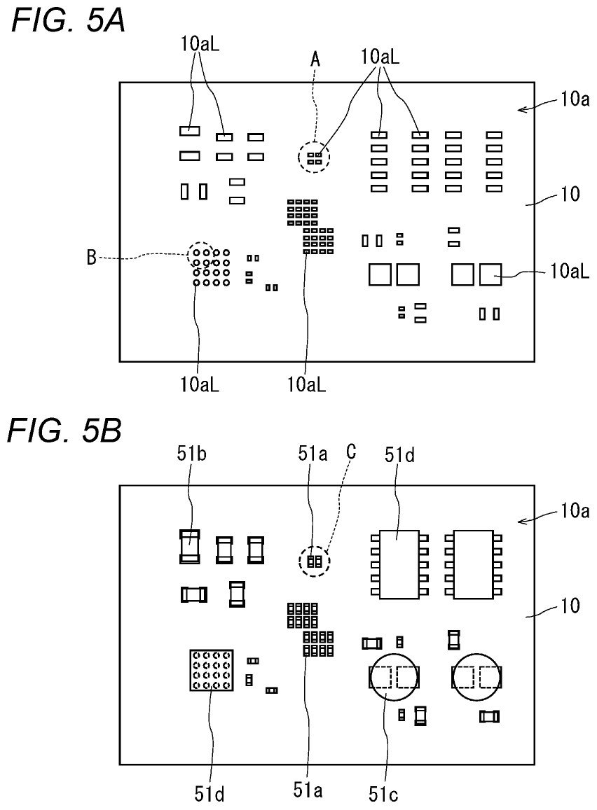

FIG. 5A shows an example of the arrangement of the first lands 10aL formed on the first surface 10a of the circuit board 10. The first lands 10aL have various shapes and sizes depending on the components to be mounted. FIG. 5B shows a top view of the circuit board 10 on which the plurality of first components are arranged on the first lands 10aL shown in FIG. 5A. In the example shown in FIG. 5B, the plurality of first components include micro components (chip components) 51a, small chip components 51b, large components 51c, and package components 51d. Examples of the large components 51c include capacitors. Examples of the package components 51d include BGAs, CSPs, flat package ICs, and the like.

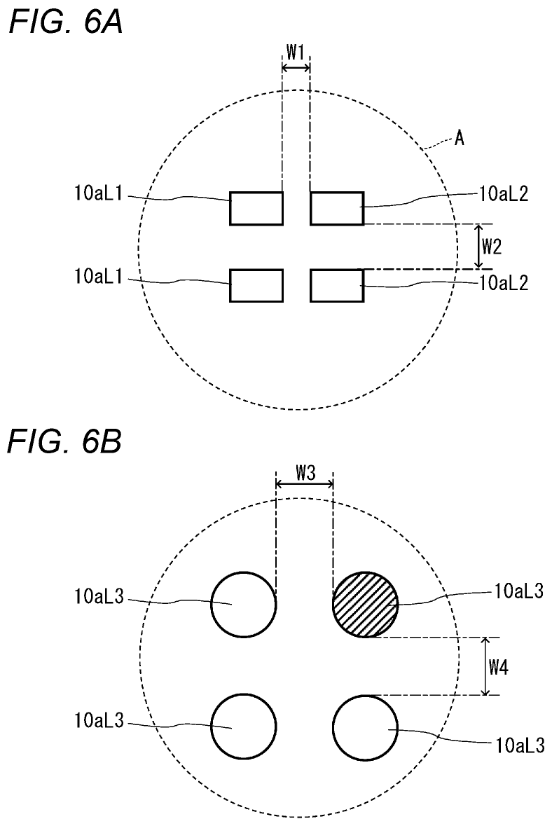

FIG. 6A is an enlarged view of a region A in FIG. 5A. The lands shown in FIG. 6A include two first lands 10aL1 to which one micro component (first component) 51a1 is connected, and two first lands 10aL2 to which an adjacent micro component (first component) 51a2 is connected. In the example shown in FIG. 6, the distance between the lands to which different components are connected is W1. The distance between the lands to which the same component is connected is W2. The number of “lands adjacent with a distance of 0.1 mm or less therebetween” described above is determined taking into account both distances W1 and W2. That is, if either the distance W1 or W2 is 0.1 mm or less, the two adjacent lands with that distance therebetween are counted in the number of “lands adjacent with a distance of 0.1 mm or less therebetween”.

FIG. 6B is an enlarged view of a region B in FIG. 5A. The lands shown in FIG. 6B include a plurality of first lands 10aL3 to which terminal portions called bumps on CSPs and BGAs are connected. Many of the CSPs and BGAs include a plurality of bumps arranged in a grid pattern, and the plurality of first lands 10aL3 are formed at positions that correspond to that arrangement. In general, as the bump size decreases, the area of each first land 10aL3 (shown by hatching) and distances W3 and W4 between the adjacent first lands 10aL3 also decrease, making soldering more difficult. The number of “lands adjacent with a distance of 0.1 mm or less therebetween” described above is determined taking into account both distances W3 and W4. That is, if either the distance W3 or W4 is 0.1 mm or less, the two adjacent lands with that distance therebetween are counted in the number of “lands adjacent with a distance of 0.1 mm or less therebetween”.

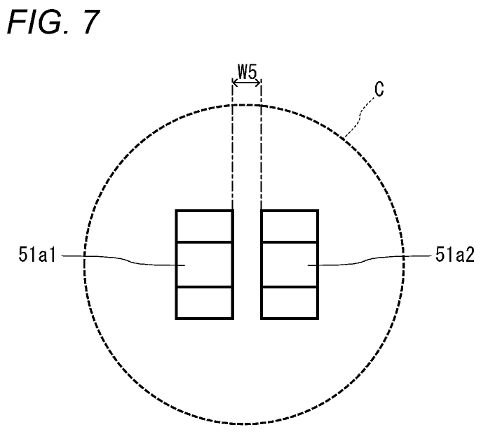

FIG. 7 is an enlarged view of a region C in FIG. 5B. Two micro components (first components) 51al and 51a2 are arranged in the region C. FIG. 7 shows a distance W5 between the two adjacent micro components (micro components 51a1 and 51a2).

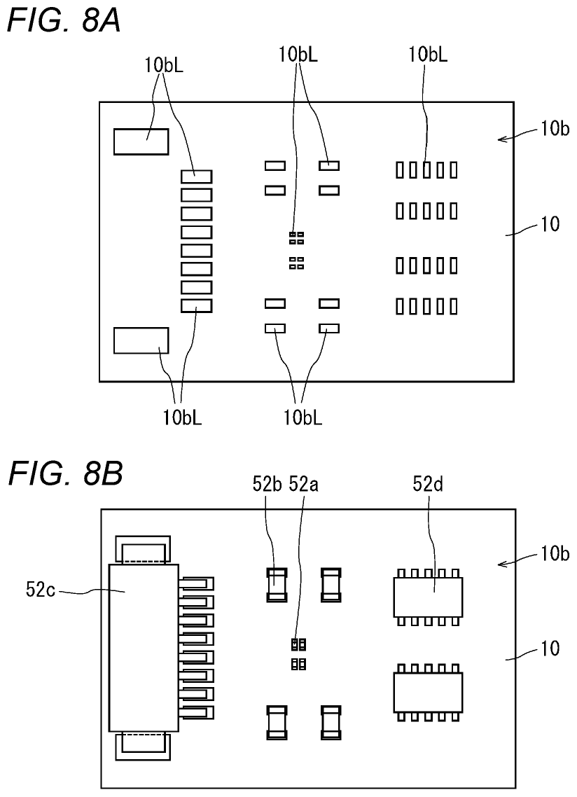

FIG. 8A shows an example of the arrangement of the second lands 10bL formed on the second surface 10b of the circuit board 10. The second lands 10bL have various shapes and sizes depending on the components to be mounted. FIG. 8B is a top view of the circuit board 10 on which a plurality of second components are arranged on the second lands 10bL shown in FIG. 8A. In the example shown in FIG. 8B, the plurality of second components include micro components (chip components) 52a, small chip components 52b, a large component 52c, and package components 52d. In the example shown in FIG. 8, the large component 52c is a connector. Examples of the package components 52d include the package components described above.

In the first embodiment, of the two surfaces (first surface 10a and second surface 10b) of the circuit board 10, the first surface 10a is described as the surface on which soldering is more difficult, and land patterns and components that are more difficult to solder may be concentrated on the first surface 10a at the design stage of the circuit board 10.

### Supplementary Notes

The above description discloses the following technologies.

### Technique 1

A manufacturing method for a component mounting board including a circuit board having a first surface and a second surface on an opposite side to the first surface, and a plurality of components mounted on both surfaces of the circuit board, the method including, in order:
a solder precoat portion formation step of forming solder precoat portions on a plurality of first lands on the first surface of the circuit board;
a first arrangement step of arranging a plurality of first components on the solder precoat portions;
a first reflow step of soldering the plurality of first components by heating the circuit board on which the plurality of first components are arranged;
a solder paste application step of applying solder paste to a plurality of second lands on the second surface of the circuit board;
a second arrangement step of arranging a plurality of second components on the solder paste; and
a second reflow step of soldering the plurality of second components by heating the circuit board on which the plurality of second components are arranged,
wherein soldering on the first surface is more difficult than soldering on the second surface.

### Technique 2

The manufacturing method according to technique 1,
wherein the plurality of first components include micro components having a size not larger than an 0402 size prescribed by JIS, and
the micro components included in the plurality of first components are greater in number than the micro components included in the plurality of second components.

### Technique 3

The manufacturing method according to technique 1 or 2, wherein lands having an area of 0.04 mm² or less among the plurality of first lands are greater in number than lands having an area of 0.04 mm² or less among the plurality of second lands.

### Technique 4

The manufacturing method according to any one of techniques 1 to 3, wherein lands adjacent with a distance of 0.1 mm or less therebetween among the plurality of first lands are greater in number than lands adjacent with a distance of 0.1 mm or less therebetween among the plurality of second lands.

### Technique 5

The manufacturing method according to according to any one of techniques 1 to 4,
wherein the plurality of first components include micro components having a size not larger than an 0402 size prescribed by JIS, and
the micro components adjacent with a distance of 0.1 mm or less therebetween among the plurality of first components are greater in number than the micro components adjacent with a distance of 0.1 mm or less therebetween among the plurality of second components.

### Technique 6

The manufacturing method according to any one of techniques 1 to 5, further including a flattening step of pressing down the solder precoat portions before the first arrangement step.

### Technique 7

The manufacturing method according to technique 6, wherein the flattening step is implemented in a state where the circuit board is supported by a flat support base.

### Technique 8

The manufacturing method according to any one of techniques 1 to 7, wherein each step of mounting the plurality of second components on the second surface is performed in a state where the circuit board is supported by a support means having a structure that does not interfere with the plurality of first components soldered to the first surface.

### Technique 9

A manufacturing method for a component mounting board including a circuit board having a first surface and a second surface on an opposite side to the first surface, and a plurality of components mounted on both surfaces of the circuit board, the method including:
a solder precoat portion formation step of forming solder precoat portions on a plurality of first lands on the first surface of the circuit board;
a first arrangement step of arranging a plurality of first components on the solder precoat portions;
a first reflow step of soldering the plurality of first components by heating the circuit board on which the plurality of first components are arranged;
a solder paste application step of applying solder paste to a plurality of second lands on the second surface of the circuit board;
a second arrangement step of arranging a plurality of second components on the solder paste; and
a second reflow step of soldering the plurality of second components by heating the circuit board on which the plurality of second components are arranged,
wherein lands having an area of 0.04 mm² or less among the plurality of first lands are greater in number than lands having an area of 0.04 mm² among the plurality of second lands.

### Technique 10

A manufacturing method for a component mounting board including a circuit board having a first surface and a second surface on an opposite side to the first surface, and a plurality of components mounted on both surfaces of the circuit board, the method including:
a solder precoat portion formation step of forming solder precoat portions on a plurality of first lands on the first surface of the circuit board;
a first arrangement step of arranging a plurality of first components on the solder precoat portions;
a first reflow step of soldering the plurality of first components by heating the circuit board on which the plurality of first components are arranged;
a solder paste application step of applying solder paste to a plurality of second lands on the second surface of the circuit board;
a second arrangement step of arranging a plurality of second components on the solder paste; and
a second reflow step of soldering the plurality of second components by heating the circuit board on which the plurality of second components are arranged,
wherein lands adjacent with a distance of 0.1 mm or less therebetween among the plurality of first lands are greater in number than lands adjacent with a distance of 0.1 mm or less therebetween among the plurality of second lands.

### Technique 11

A manufacturing method for a component mounting board including a circuit board having a first surface and a second surface on an opposite side to the first surface, and a plurality of components mounted on both surfaces of the circuit board, the method including:
a solder precoat portion formation step of forming solder precoat portions on a plurality of first lands on the first surface of the circuit board;
a first arrangement step of arranging a plurality of first components on the solder precoat portions;
a first reflow step of soldering the plurality of first components by heating the circuit board on which the plurality of first components are arranged;
a solder paste application step of applying solder paste to a plurality of second lands on the second surface of the circuit board;
a second arrangement step of arranging a plurality of second components on the solder paste; and
a second reflow step of soldering the plurality of second components by heating the circuit board on which the plurality of second components are arranged,
wherein the plurality of first components include micro components having a size not larger than an 0402 size prescribed by JIS, and
the micro components adjacent with a distance of 0.1 mm or less therebetween among the plurality of first components are greater in number than the micro components adjacent with a distance of 0.1 mm or less therebetween among the plurality of second components.

### Technique 12

The manufacturing method according to any one of techniques 9 to 11, further including a flattening step of pressing down the solder precoat portions before the first arrangement step.

### Technique 13

The manufacturing method according to technique 12, wherein the flattening step is implemented in a state where the circuit board is supported by a flat support base.

### Technique 14

The manufacturing method according to any one of techniques 9 to 13, wherein each step of mounting the plurality of second components on the second surface is performed in a state where the circuit board is supported by a support means having a structure that does not interfere with the plurality of first components soldered to the first surface.

The present disclosure can be used as a manufacturing method for a component mounting substrate.

Although the present invention has been described in terms of presently preferred embodiments, such disclosure should not be interpreted as limiting. Various modifications and variations will no doubt become apparent to those skilled in the art to which the present invention pertains upon reading the above disclosure. It is therefore intended that the appended claims be interpreted as including all modifications and variations without departing from the true spirit and scope of the present invention.

### Reference Signs List

10: circuit board, 10a: first surface, 10aL: first land, 10b: second surface, 10bL: second land, 10x: component mounting board, 11: substrate, 21: solder precoat portion, 21x, 31x: solder, 31: solder paste, 51: first component, 52: second component

What is claimed is:

1. A manufacturing method for a component mounting board including a circuit board having a first surface and a second surface on an opposite side to the first surface, and a plurality of components mounted on both surfaces of the circuit board, the method comprising, in order:
a solder precoat portion formation step of forming solder precoat portions on a plurality of first lands on the first surface of the circuit board;
a first arrangement step of arranging a plurality of first components on the solder precoat portions;
a first reflow step of soldering the plurality of first components by heating the circuit board on which the plurality of first components are arranged;
a solder paste application step of applying solder paste to a plurality of second lands on the second surface of the circuit board;
a second arrangement step of arranging a plurality of second components on the solder paste; and
a second reflow step of soldering the plurality of second components by heating the circuit board on which the plurality of second components are arranged,
wherein soldering on the first surface is more difficult than soldering on the second surface.

2. The manufacturing method according to claim 1,
wherein the plurality of first components include micro components having a size not larger than an 0402 size prescribed by JIS, and
the micro components included in the plurality of first components are greater in number than the micro components included in the plurality of second components.

3. The manufacturing method according to claim 1, wherein lands having an area of 0.04 mm² or less among the plurality of first lands are greater in number than lands having an area of 0.04 mm² or less among the plurality of second lands.

4. The manufacturing method according to claim 1, wherein lands adjacent with a distance of 0.1 mm or less therebetween among the plurality of first lands are greater in number than lands adjacent with a distance of 0.1 mm or less therebetween among the plurality of second lands.

5. The manufacturing method according to claim 1,
wherein the plurality of first components include micro components having a size not larger than an 0402 size prescribed by JIS, and
the micro components adjacent with a distance of 0.1 mm or less therebetween among the plurality of first components are greater in number than the micro components adjacent with a distance of 0.1 mm or less therebetween among the plurality of second components.

6. The manufacturing method according to claim 1, further comprising a flattening step of pressing down the solder precoat portions before the first arrangement step.

7. The manufacturing method according to claim 6, wherein the flattening step is implemented in a state where the circuit board is supported by a flat support base.

8. The manufacturing method according to claim 7, wherein each step of mounting the plurality of second components on the second surface is performed in a state where the circuit board is supported by a support means having a structure that does not interfere with the plurality of first components soldered to the first surface.

9. A manufacturing method for a component mounting board including a circuit board having a first surface and a second surface on an opposite side to the first surface, and a plurality of components mounted on both surfaces of the circuit board, the method comprising:
a solder precoat portion formation step of forming solder precoat portions on a plurality of first lands on the first surface of the circuit board;
a first arrangement step of arranging a plurality of first components on the solder precoat portions;
a first reflow step of soldering the plurality of first components by heating the circuit board on which the plurality of first components are arranged;
a solder paste application step of applying solder paste to a plurality of second lands on the second surface of the circuit board;
a second arrangement step of arranging a plurality of second components on the solder paste; and
a second reflow step of soldering the plurality of second components by heating the circuit board on which the plurality of second components are arranged,
wherein lands having an area of 0.04 mm² or less among the plurality of first lands are greater in number than lands having an area of 0.04 mm² among the plurality of second lands.

10. A manufacturing method for a component mounting board including a circuit board having a first surface and a second surface on an opposite side to the first surface, and a plurality of components mounted on both surfaces of the circuit board, the method comprising:
a solder precoat portion formation step of forming solder precoat portions on a plurality of first lands on the first surface of the circuit board;
a first arrangement step of arranging a plurality of first components on the solder precoat portions;
a first reflow step of soldering the plurality of first components by heating the circuit board on which the plurality of first components are arranged;
a solder paste application step of applying solder paste to a plurality of second lands on the second surface of the circuit board;
a second arrangement step of arranging a plurality of second components on the solder paste; and
a second reflow step of soldering the plurality of second components by heating the circuit board on which the plurality of second components are arranged,
wherein lands adjacent with a distance of 0.1 mm or less therebetween among the plurality of first lands are greater in number than lands adjacent with a distance of 0.1 mm or less therebetween among the plurality of second lands.

11. A manufacturing method for a component mounting board including a circuit board having a first surface and a second surface on an opposite side to the first surface, and a plurality of components mounted on both surfaces of the circuit board, the method comprising:
a solder precoat portion formation step of forming solder precoat portions on a plurality of first lands on the first surface of the circuit board;
a first arrangement step of arranging a plurality of first components on the solder precoat portions;
a first reflow step of soldering the plurality of first components by heating the circuit board on which the plurality of first components are arranged;
a solder paste application step of applying solder paste to a plurality of second lands on the second surface of the circuit board;
a second arrangement step of arranging a plurality of second components on the solder paste; and
a second reflow step of soldering the plurality of second components by heating the circuit board on which the plurality of second components are arranged,
wherein the plurality of first components include micro components having a size not larger than an 0402 size prescribed by JIS, and
the micro components adjacent with a distance of 0.1 mm or less therebetween among the plurality of first components are greater in number than the micro components adjacent with a distance of 0.1 mm or less therebetween among the plurality of second components.

12. The manufacturing method according to claim 9, further comprising a flattening step of pressing down the solder precoat portions before the first arrangement step.

13. The manufacturing method according to claim 12, wherein the flattening step is implemented in a state where the circuit board is supported by a flat support base.

14. The manufacturing method according to claim 13, wherein each step of mounting the plurality of second components on the second surface is performed in a state where the circuit board is supported by a support means having a structure that does not interfere with the plurality of first components soldered to the first surface.

15. The manufacturing method according to claim 10, further comprising a flattening step of pressing down the solder precoat portions before the first arrangement step.

16. The manufacturing method according to claim 15, wherein the flattening step is implemented in a state where the circuit board is supported by a flat support base.

17. The manufacturing method according to claim 16, wherein each step of mounting the plurality of second components on the second surface is performed in a state where the circuit board is supported by a support means having a structure that does not interfere with the plurality of first components soldered to the first surface.

18. The manufacturing method according to claim 11, further comprising a flattening step of pressing down the solder precoat portions before the first arrangement step.

19. The manufacturing method according to claim 18, wherein the flattening step is implemented in a state where the circuit board is supported by a flat support base.

20. The manufacturing method according to claim 19, wherein each step of mounting the plurality of second components on the second surface is performed in a state where the circuit board is supported by a support means having a structure that does not interfere with the plurality of first components soldered to the first surface.
